(19) United States
(12) Patent Application Publication
(10) Pub. No.: US 2025/0135423 A1
(43) Pub. Date: May 1, 2025

(54) CONDUIT, SYSTEMS AND METHODS FOR FLUID TEMPERATURE CONTROL

(71) Applicant: Applied Materials, Inc., Santa Clara, CA (US)

(72) Inventor: Kevin Griffin, Livermore, CA (US)

(73) Assignee: Applied Materials, Inc., Santa Clara, CA (US)

(21) Appl. No.: 18/383,703

(22) Filed: Oct. 25, 2023

(51) Int. Cl. B01J 4/00

(52) U.S. Cl. CPC B01J 4/008; B01J 2204/007

(57) ABSTRACT

Chemical deliver conduits, systems for substrate processing and methods for supplying a chemical to a substrate processing chamber are described. The conduit has a length and connects a vessel containing the chemical to the substrate processing chamber. The conduit comprises an outer channel surrounding an inner channel. The outer channel is in fluid communication with source of a heat transfer fluid, and the inner channel is in fluid communication with the vessel containing the chemical.

### FIELD

The disclosure pertains to conduit, systems and methods for delivering a chemical to a substrate processing chamber. More specifically, embodiments of the disclosure are directed to conduits, systems and methods for delivering chemical and controlling the temperature of the chemical in the conduit between the chemical source and the substrate processing chamber.

### BACKGROUND

Substrate processing chambers used in the manufacture of semiconductor devices called chips require the transport of one or more chemicals to process substrates or wafers. During transport of a chemical through a conduit, chemical may be subjected to a wide range of temperatures, depending upon conduit location (e.g. controlled or ambient environmental conditions), length of the conduit, and fluid pressure within the conduit. These variations in may lead to condensation if the temperature becomes too low, or decomposition of the chemical or corrosion if the temperature becomes too high.

To avoid the problems associated with vapor condensation, it is a common practice in the semiconductor industry, for example, to heat the conduits that are used to transport certain fluids and vapors to and from processing equipment. Such fluid heating is also helpful to maintain the fluids at a proper temperature, such that state conversion, e.g. from gas to liquid, does not occur. Thus, it is beneficial to maintain such chemicals at a desired temperature, at a corresponding unsaturated vapor pressure. Heating is usually provided by external electrical heater jackets around the chemical container and delivery pipe. These heater jackets result in large temperature variations along the length of the conduit, which can lead to the aforementioned problems.

Therefore, there is a need for apparatus and methods to provide temperature control of chemicals delivered to substrate processing chambers via conduits.

### SUMMARY

One or more embodiments of the disclosure are directed to a substrate processing system comprising a substrate processing chamber configured to perform a chemical reaction on a surface of a substrate; a vessel configured to contain a chemical used in the chemical reaction; and a conduit having a length and connecting the vessel to a chemical delivery system connected to the substrate processing chamber and configured to deliver the chemical as a vapor to the substrate processing chamber, the conduit comprising an outer channel surrounding an inner channel and in fluid communication with source of a heat transfer fluid and the inner channel in fluid communication with the vessel.

Additional embodiments of the disclosure are directed to a method of delivering a chemical to a substrate processing chamber, the method comprising flowing from a vessel containing the chemical through an inner channel of a length of a conduit; and maintaining the chemical flowing in the inner channel at a temperature variation of less than 10° C. along the length of the conduit between the vessel and a chemical delivery system which delivers the chemical as a vapor to the substrate processing chamber with a heat exchange fluid surrounding the inner channel.

### BRIEF DESCRIPTION OF THE DRAWINGS

So that the manner in which the exemplary embodiments of the present invention are attained and can be understood in detail, a more particular description of the disclosure, briefly summarized above, may be had by reference to the embodiments thereof which are illustrated in the appended drawings. It is to be appreciated that certain well known processes are not discussed herein in order to not obscure the invention.

FIG. 1 shows a schematic of system in accordance with one or more embodiments of the disclosure;

FIG. 2 shows a cross-sectional view of a conduit in accordance with a first embodiment of the disclosure;

FIG. 3 shows a cross-sectional view of a conduit in accordance with a second embodiment of the disclosure; and

FIG. 4 is a flowchart showing a method of processing a substrate according to one or more embodiments of the disclosure.

### DETAILED DESCRIPTION

One or more embodiments of the disclosure provide apparatus and methods for providing temperature control delivery of precursors to processing chambers.

In the processing of thin films on a semiconductor substrate, for example, as in the formation of a metal oxide films, liquid source chemicals are often used. These liquids are typically stored in source tanks and are delivered as vapors to a substrate processing chamber such as a deposition chamber or an etching chamber (or a combined deposition/etching chamber) using a delivery system wherein each liquid flows through a separate conduit and liquid flow meter (to provide individual control of the flow rate of each reactant) and then is injected as a vapor into a manifold. The vapors flowing in the manifold are then introduced into the substrate processing chamber.

As mentioned above, condensation of vaporized liquid chemicals presents problems during the processing of substrates in processing chambers. For example, if the temperature at a particular point along the delivery conduit is too low (a cold spot), condensation of a previously vaporized liquid chemical such as a precursor source or component may occur at that point in conduit. On the other hand, maintenance of too high a temperature in the conduit (to prevent such undesirable condensation) can lead to instabilities in the flow rate control of that particular chemical.

According to one or more embodiments of the disclosure, a heat transfer fluid is used to heat or cool a chemical that is delivered to a substrate processing chamber. As used in this disclosure, “heat transfer fluid” refers to a fluid, for example, a liquid, that cools or heats a chemical adjacent to the heat transfer fluid. In one or more embodiments, the heat transfer fluid is a liquid contained and flowed in a conduit such as a pipe or a closed line adjacent to or surrounding a chemical that is delivered to the substrate processing chamber. An inner conduit contains the chemical to be heated/cooled, and an outer conduit containing the heat transfer fluid surrounds the inner conduit. It was discovered that a heat transfer fluid makes much better contact with the wall of the inner conduit containing the chemical, which improves the heat transfer coefficient through the wall of the inner conduit. In addition, a heat transfer fluid provides a larger heat capacity of the heated/cooled fluid that a heater wrapped around the inner conduit and is therefore better able to uniformly heated/cool the chemical delivered to the substrate processing chamber.

In one or more embodiments, a chemical is stored in a vessel, vaporized, and delivered to a substrate processing chamber in a conduit. The conduit used to transport the chemical is surrounded by a heat transfer fluid in an outer conduit, which heats and/or cools the chemical in the inner conduit. A heat exchanger in fluid communication with the outer conduit flows temperature-controlled heat transfer fluid through the outer conduit, which heats or cools the chemical in the inner conduit to a predetermined temperature. In one or more embodiments, the predetermined temperature is a range of temperatures at which the chemical in the inner conduit does not condense.

One or more embodiments of the disclosure solves a persistent and difficult problem concerning certain chemicals, particular chemicals used in substrate processing operations that are sensitive to temperature variations and are susceptible to condensing when not maintained in a narrow temperature range. In one or more embodiments, chemicals such as metal precursors used in substrate processing chambers used to manufacture of metal thin films can be delivered in nearly pure vapor form, enabling the chemical to be delivered with more precise concentration control. When there is even a small amount of chemical in the liquid state in the chemical delivery conduit, it is more difficult to control concentration of the chemical delivered to a substrate surface being processed in a substrate processing chamber. One or more embodiments described herein provides a solution to long-standing problem that plagued the delivery of unstable chemicals such as metal film precursors to substrate processing chambers. In some embodiments, the methods and systems of the present disclosure enable easier to deal tight temperature control in 3 to 5° C. temperature window along the length of conduit up to 100 feet in length. In large scale manufacturing environments, often the chemicals delivered to the substrate processing chambers may not be in the same room as the substrate processing chambers which are usually required to be maintained to clean room standards, and therefore the chemicals used in substrate processing may be store in a separate room, wing or floor of a semiconductor device manufacturing facility.

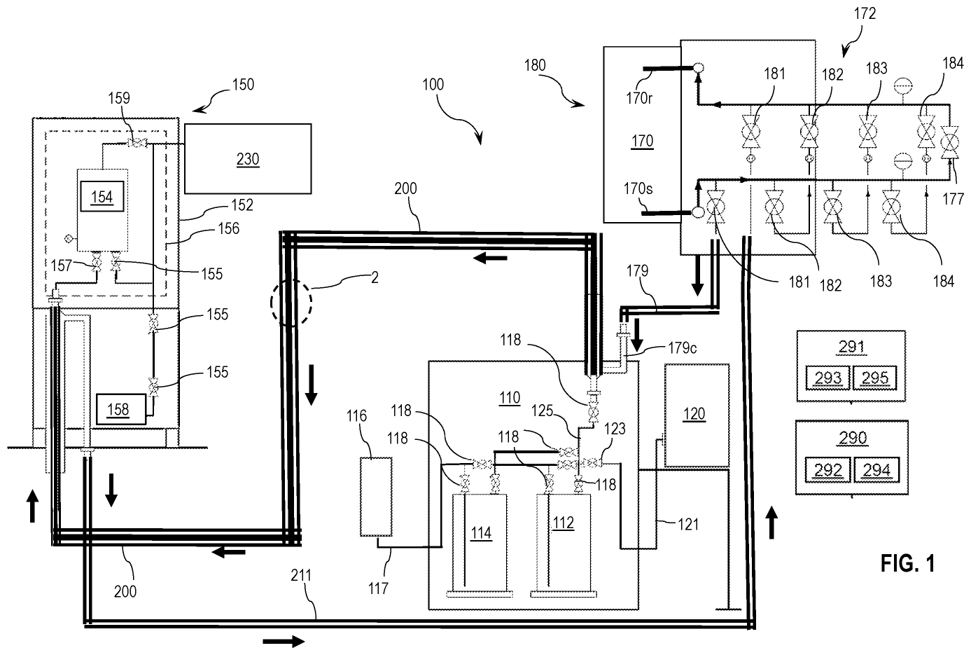

Referring to FIG. 1, a schematic of an embodiment of a substrate processing system 100 is shown. The substrate processing system 100 comprises a vapor delivery panel 110 which is fluidly connected to a chemical delivery system 150 and a heat exchanger 180. One embodiment of the disclosure comprises a subsystem of the substrate processing system 100 comprising the vapor delivery panel 110 fluidly connected to the chemical delivery system 150 and the heat exchanger 180. As used herein, the phrased “fluidly connected” or “in fluid communication” refer to the different systems or portions of the systems being connected by a conduit, line or pipe that allows a fluid to flow from one system of portion of a system to another system or portion of a system. The conduits, pipes or lines may be in the form of a metal material having an appropriate diameter and wall thickness used to deliver chemicals used in semiconductor processing chambers. For some chemicals, the conduits, lines or pipes may comprise a polymer or plastic.

In the substrate processing system 100 shown, the chemical delivery system 150 is in fluid communication with a substrate processing chamber 230 configured to perform a chemical reaction on a surface of a substrate. The substrate processing chamber 230 according to one or more embodiments can be a deposition chamber, for example, a chemical vapor deposition chamber, a cyclical deposition chamber, an atomic layer deposition chamber, an etching chamber or other chambers used in the processing the semiconductor devices.

The vapor delivery panel 110 in the embodiment shown comprises a vessel 112 configured to contain a chemical used in the chemical reaction. The embodiment shown further includes an optional spare vessel 114 configured to contain spare chemical. The vessel 112 and the spare vessel 114 may be in the form of tanks configured to hold chemicals in liquid or solid form used in substrate processing chambers that can perform operations such as etching, deposition of metal and dielectric films to form semiconductor devices. The vapor delivery panel 110 may comprise further components that are typically used to supply chemicals to substrate processing chambers. For example a purge gas tank 116 is fluidly connected by purge gas line 117 to the vessel 112 and the spare vessel 114. Valves 118 control the flow of chemical from the vessel 112 and spare vessel 114 through supply line 125A scrubber system 120 including a pump is fluidly connected to the vapor delivery panel by scrubber line including scrubber valve 121.

The chemical delivery system 150 comprises an enclosure 152 enclosing a vapor receiving tank 154 which is enclosed by a heated enclosure 156. A purge gas supply 158 supplies a purge gas, such as an inert gas (e.g., Ar), and the flow of the purge gas may be controlled by purge gas valves 155.

The heat exchanger 180 comprises heating and cooling unit 170 that can be thermostatically controlled to supply a desired amount of heating or cooling of the heat transfer fluid that circulates through the heating and cooling unit 170. The heat exchanger 180 further include a manifold 172 comprising first chamber valves 181, second chamber valves 182, third chamber valves 183, fourth chamber valves 184 and a minimum flow bypass valve 177. A heat transfer fluid circulates through from the heating and cooling unit 170 through the manifold 172 via a heat exchanger supply line 170s and a heat exchanger return line 170r. The manifold 172 is configured to distribute the heat exchange fluid that is heated and/or cooled in the heating and cooling unit 170 to be flowed to and from a plurality of substrate processing chambers. In the embodiment shown, the heat exchanger 180 including the manifold 172 is configured to supply heat exchange fluid to four separate substrate processing chambers or four distinct regions of a single substrate processing chamber. In the embodiment shown, first chamber valves 181 are in fluid communication with a substrate processing chamber 230 and supply heat transfer fluid that is heated and cooled in the heat exchanger 180.

The heat transfer fluid that is heated and cooled in the heat exchanger 180 is flowed through a heat transfer fluid supply line 179 from the manifold 172. The heat transfer fluid flows in the direction of the arrows shown in FIG. 1, from a heat transfer fluid supply line 179 to a heat transfer fluid connection 179c that connects to a conduit 200 which fluidly connect the heat exchanger 180 and the chemical delivery system 150. As will be discussed in more detail, the conduit 190 comprises at least two flow channels, a first channel to deliver chemical from the vapor delivery panel 110 to the chemical delivery system 150, and a second channel that surrounds the one channel that delivers the chemical from the vapor delivery panel 110 to the chemical delivery system. The second channel surrounds the first channel.

The conduit 200 has a length which is defined by a distance between the vapor delivery panel 110 and the chemical delivery system 150. The conduit 200 may be referred to as a dual fluid delivery conduit and is heat exchange fluid temperature regulated. The darker center line in FIG. 1 is an inner channel 206 connecting the vessel 112 containing the chemical to be delivered to a substrate processing chamber 230 to the substrate processing chamber 230. The conduit further comprises an outer channel 202 surrounding the inner channel 206. The outer channel 202 is in fluid communication with the source of a heat transfer fluid supplied at the heat exchanger 180 and the inner channel 206 is in fluid communication with the vessel 112 and the chemical delivery system 150.

Thus, in the substrate processing system shown, the source of the heat transfer fluid further comprises the heat exchanger 180 configured to heat and cool the heat transfer fluid that flows in the outer channel 202 of the conduit 200. After the heat transfer fluid flows into heat transfer fluid connection 179c that is connected to the conduit 200 which fluidly connect the heat exchanger 180, the heat transfer fluid flows in the outer channel 202, keeping the chemical flowing from the vessel 112 at a predetermined temperature. The heat transfer fluid flows to the chemical delivery system 105 and chemical valve 157 is opened to allow the chemical flowing in vapor form in the inner channel 206 into the vapor receiving tank 154, which is enclosed in the heated enclosure 156, maintaining the chemical in vapor form at the predetermined or target temperature. When a substrate processing operation commences, chamber valve 159 opens to allow the vapor chemical to flow into the substrate processing chamber 230.

Heat transfer fluid is periodically or continuously circulated from the chemical delivery system back to the heat exchanger by the heat exchange fluid return line 211.

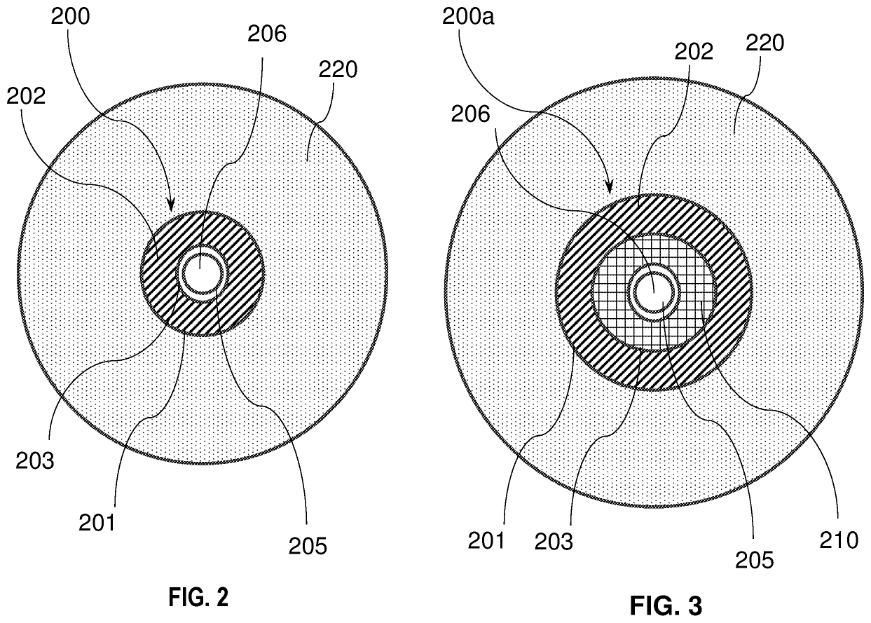

FIG. 2 is a cross sectional view of the conduit 200 shown in FIG. 1. As shown in FIG. 2, the conduit 200 is wrapped in a layer of insulation 220. The layer of insulation can comprise any suitable fiberglass or other insulation used to insulate pipes or conduits in industrial processes that involve the flow of vapor chemicals and gases.

The outer channel 202 of the conduit is formed by an outer wall 201 and an inner wall 203, and heat transfer fluid flows in the outer channel 202 between the outer wall 201 and the inner wall 201. In the embodiment shown, the inner channel 206 is defined by an exterior wall 205 that is separate from the inner wall 203 of the outer channel. In this way, the outer channel may be a separate pipe or line that has the inner channel 206 formed by the separate exterior wall that forms the inner channel. The diameter of the inner channel may be any suitable diameter to permit the chemical to be delivered to the chemical delivery system 150 and to the substrate processing chamber. A non-limiting example of the diameter of the inner conduit is in a range of ¼ inch to ½ inch. Similarly, the diameter of the outer channel 202 will be determined by the volume of the heat exchange fluid needed to bring the chemical in the inner conduit to the desired temperature to prevent condensation and maintain the chemical in a target or predetermined temperature range to prevent condensation of the chemical and to maintain the chemical in the vapor state. It will be understood that the volume and flow rate of the heat exchange fluid will be determined by the vapor pressure of the chemical to be delivered to the substrate processing chamber 230, the volume of vapor flowing in the inner channel 206 and the heat transfer fluid used for the particular substrate processing operation. The actual values can be determined experimentally or by using modeling and/or heat transfer calculations.

FIG. 2A shows an embodiment of a conduit 200a that comprises the inner channel 206 and outer channel 202 similar to FIG. 2. The conduit 200a in FIG. 3 comprises an additional intermediate channel 210 separating the outer channel 202 and the inner channel 206. In one or more embodiments, the intermediate channel 210 contains an inert material. The inert material can be a solid, a liquid or a gas. Non-limiting examples of inert materials include hydrogen gas, helium water, steam, and heating oil. In one or more embodiments, the inert material is a conductive conformal media. Hydrogen has a thermal conductivity of 0.17 W/m*K. Helium has a thermal conductivity of 0.15 W/m*K. Water has a thermal conductivity of 0.61 W/m*K. Steam has a thermal conductivity of 0.081 W/m*K. Heating oil has a thermal conductivity of 0.12 W/m*K.

According to one or more embodiments, the configuration in FIG. 2 provides a slightly better thermal uniformity along a 50 to 60 foot length of the conduit 200. The presence of the inert material reduces the heat transfer between the heat transfer fluid and the chemical in the inner channel 206 by about 1 degree Centigrade or more.

In specific embodiments, the inert material is a fluid, such as a liquid. According to one or more embodiments, the intermediate channel 210 containing an inert material provides separation of the chemical in the inner channel 206 and the heat transfer fluid in the outer channel 202. The lower pressure in the intermediate channel can be used to detect a leak of the heat transfer fluid or the chemical.

According to one or more embodiments, the heat transfer fluid in the outer channel 202 is configured to maintain the chemical in the inner channel at a temperature variation of less than 10° C. along the length of the conduit between the vessel 112 and the chemical delivery system 150. In some embodiments, the length of the conduit between the vessel and the substrate processing chamber is at least 60 feet (18.28 meters) and the temperature variation is less than 5° C., less than 4° C., less than 3° C., or less than 2° C. along the length of the conduit between the vessel and the substrate processing chamber. In some embodiments, the temperature is maintained at a predetermined or target value in a range of from 150° C. to 250° C., for example, 180° C. or 200° C. It will be appreciated that the predetermined or target value is based upon the vapor pressure of a particular chemical to be delivered to a substrate processing chamber.

In one example, using a system as shown in FIG. 1, a molybdenum halide precursor was maintained at a predetermined or target temperature of 200° cover a length of conduit of at least 20 feet (6.10 meters), 30 feet (9.14 meters), 40 feet (12.19 meters), 50 feet (15.24 meters) or 60 feet (18.29 meters) at a flow rate of 1154 sccm and 300 Torr supply pressure, within 2-3° C. of 200° C., preventing condensation of the molybdenum halide precursor. The heat exchange fluid was a Galden® fluid, but other heat exchange fluids such as hydrocarbon mineral oils, or silicone oil heat exchange fluids may be used. In one or more embodiments, the conduits, systems and methods describer herein are configured to control the temperature over the range of lengths provided immediately above to within 5° C., within 4° C., within 3° C., or within 2° C. over the entire length of the conduit at a chemical vapor delivery temperature in a range of from 120-250° C., 120-240° C., 120-230° C., 120-220° C., 120-210° C., 120-200° C., 120-190° C., 120-180° C., for example at 150° C., 160° C., 170° C., 180° C., or 200° C. Due to the precise and efficient temperature control of the heat exchange fluids having the properties described herein and surrounding the inner conduit with the heat exchange fluid, precise temperature control of the chemical vapor form is achieved, which was not presently obtainable with existing delivery conduit and systems.

In one or more embodiments, the heat transfer fluid comprises a hydrocarbon mineral oil, a silicone oil based fluid fluorinated fluid. In one or more embodiments, the heat transfer fluid is a perfluorinated, inert polyether fluid, for example, a Galden® fluid. In one or more embodiments, the heat transfer fluid has a boiling point in a range of from 55° C. to 270° C. and an operating temperature in a range of from −70° C. to 290° C. In one or more embodiments, the heat transfer fluid has a specific heat at 25° C. of 0.23 cal/g*C. It will be appreciated that a skilled artisan would select the proper grade of fluid with the heat transfer properties based on the desired vapor delivery temperature. The embodiments described herein provide an additional degree of freedom in controlling the delivery temperature of chemicals used in semiconductor substrate processing chambers. While operating at a higher temperature may address condensation of certain chemicals in vapor form, for some chemicals, increasing the temperature may increase cause corrosion of the delivery conduit. Embodiments of the present disclosure solve a difficult problem of preventing both condensation and corrosion of the conduit by controlling the vapor delivery temperature in a narrow temperature range.

Referring back to FIG. 1, the system 100 according to one or more embodiments can comprise a first controller 291. The first controller 291 according to one or more embodiments comprises a first processor 293, a first memory 295 coupled to the processor, input/output devices coupled to the first processor 293, and support circuits to provide communication between the different components of the system or apparatus, operation of the system and flow of chemical vapor to the processing chamber 230. Processes to operate the system 100 may generally be stored in the memory as a software routine that, when executed by the processor, causes the system 100 to perform methods described in the present disclosure. The software routine may also be stored and/or executed by a second processor (not shown) that is remotely located from the hardware being controlled by the processor. Some or all of the methods of the present disclosure may also be performed in hardware. As such, the methods described in this disclosure are implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The system 100 according to one or more embodiments can comprise a second controller 290. The second controller 290 according to one or more embodiments comprises a second processor 292, a second memory 294 coupled to the processor, input/output devices coupled to the second processor 292, and support circuits to provide communication between the different components of the system or apparatus, operation of the heated enclosure 156 surrounding the vapor receiving tank 154 and flow of chemical in vapor form to the processing chamber 230. The second controller 290, the second processor 292 and the second memory 294 may also control heating and cooling of the heat exchanger 180. Processes to operate the system 100 may generally be stored in the memory as a software routine that, when executed by the processor, causes the system 100 to perform methods described in the present disclosure. The software routine may also be stored and/or executed by a second processor (not shown) that is remotely located from the hardware being controlled by the processor. Some or all of the methods of the present disclosure may also be performed in hardware. As such, the methods described in this disclosure are implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The first memory 295 and the second memory 294 of one or more embodiments includes one or more of transitory memory (e.g., random access memory) and non-transitory memory (e.g., storage) and the memory of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system. The support circuits are coupled to the processor for supporting the processor in a conventional manner. Circuits may include, for example, cache, power supplies, clock circuits, input/output circuitry, subsystems, and the like.

In one or more embodiments, the system include a first controller 291 and a second controller 290 are provided to control operation of the system 100 and the substrate processing chamber 230. The first controller 291 and the second controller 290 execute instructions deliver chemical from the vessel 112 to the chemical delivery system 150 and to the substrate processing chamber 230. In some embodiments, the first controller 291 controls operation of the various valves of the vapor delivery panel 110, the chemical delivery system 150 and the heat exchanger 180 to control flow of the chemical to the process chamber and control flow and temperature of the heat transfer fluid from the heat exchanger to the chemical delivery system to maintain the chemical at a predetermined or target temperature.

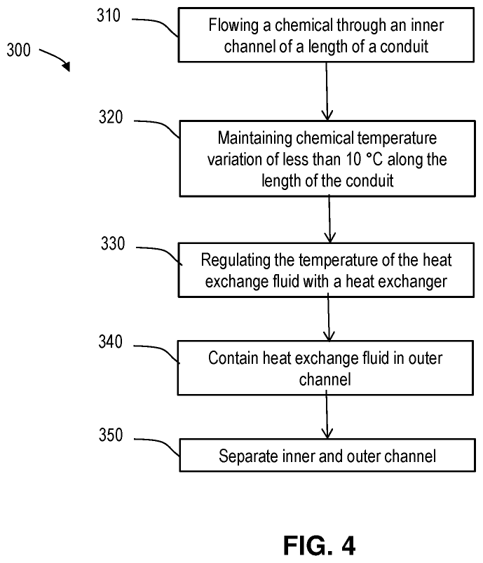

Referring now to FIG. 4, embodiments of the disclosure further pertain to a method 300 of delivering a chemical to a substrate processing chamber. The method according to one or more embodiments comprises at operation 310 flowing from a vessel containing the chemical through an inner channel of a length of a conduit. At operation 320 the method 300 includes maintaining the chemical flowing in the inner channel at a temperature variation of less than 10° C. along the length of the conduit between the vessel and a chemical delivery system which delivers the chemical as a vapor to the substrate processing chamber with a heat exchange fluid surrounding the inner channel.

The method 300 further includes at operation 330 regulating the temperature of the heat exchange fluid with a heat exchanger. The method 300 of some embodiments includes at 340 the heat exchange fluid being contained in an outer channel and flows from a heat exchanger to the chemical delivery system. In some embodiments, the method 300 optionally further comprises at 350 separating the outer channel and the inner channel with an intermediate channel containing an inert material.

According to one or more embodiments of the method, the heat transfer fluid has a boiling point in a range of from 55° C. to 270° C. and an operating temperature in a range of from −70° C. to 290° C. In one or more embodiments of the method, the heat exchange fluid comprises a fluorocarbon, such as those described above with respect to FIG. 1. In one or more embodiments of the method, the length of the conduit between the vessel and the chemical delivery system is at least 20 feet (6.10 meters), 30 feet (9.14 meters), 40 feet (12.19 meters), 50 feet (15.24 meters) or 60 feet (18.29 meters) and the temperature variation is less than 5° C. along the length of the conduit between the vessel and the chemical delivery system.

One or more method embodiments according to the present disclosure may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

For example, embodiments may further comprise a non-transitory, computer readable medium having instructions stored thereon that, when executed, causes the system of FIG. 1 to perform a method comprising flowing from a vessel containing the chemical through an inner channel of a length of a conduit and maintaining the chemical flowing in the inner channel at a temperature variation of less than 10° C. along the length of the conduit between the vessel and a chemical delivery system which delivers the chemical as a vapor to the substrate processing chamber with a heat exchange fluid surrounding the inner channel.

In specific embodiments, the non-transitory, computer readable medium having instructions stored thereon that, when executed, causes the system of FIG. 1 to flow heat transfer fluid from a heat exchanger in an outer channel of a conduit that surrounds an inner channel flowing the chemical from a vessel to a chemical delivery system. The non-transitory, computer readable medium having instructions stored thereon that, when executed monitors the temperature and sends signals to increase or decrease the temperature to maintain the chemical at a target temperature. The non-transitory, computer readable medium having instructions stored thereon that, when executed monitors the temperature and sends signals to the first controller 291 and/or second controller 290 to conduct a substrate processing operation in the substrate processing chamber. The instructions may include sequentially opening and closing the various valves of the system to allow the chemical to flow as a vapor in the inner conduit and the outer channel to maintain the flow of heat exchange fluid to maintain the desired temperature. The instructions may include inputs so that when the length of the conduit between the vessel and the chemical delivery system is at least 20 feet (6.10 meters), 30 feet (9.14 meters), 40 feet (12.19 meters), 50 feet (15.24 meters) or 60 feet (18.29 meters), the temperature variation is less than 5° C. along the length of the conduit between the vessel and the chemical delivery system.

While the foregoing is directed to embodiments of the present invention, other and further embodiments of the disclosure may be devised without departing from the basic scope thereof, and the scope thereof is determined by the claims that follow.

What is claimed is:

1. A substrate processing system comprising:
a substrate processing chamber configured to perform a chemical reaction on a surface of a substrate;
a vessel configured to contain a chemical used in the chemical reaction; and
a conduit having a length and connecting the vessel to a chemical delivery system connected to the substrate processing chamber and configured to deliver the chemical as a vapor to the substrate processing chamber, the conduit comprising an outer channel surrounding an inner channel and in fluid communication with source of a heat transfer fluid and the inner channel in fluid communication with the vessel.

2. The substrate processing system of claim 1, wherein source of the heat transfer further fluid comprises a heat exchanger configured to heat and cool the heat transfer fluid that flows in the outer channel of the conduit.

3. The substrate processing system of claim 2, wherein the heat transfer fluid in the outer channel is configured to maintain the chemical in the inner channel at a temperature variation of less than 10° C. along the length of the conduit between the vessel and the chemical delivery system.

4. The substrate processing system of claim 3, wherein the length of the conduit between the vessel and the chemical delivery system is at least 20 feet (6.10 meters) and the temperature variation is less than 5° C. along the length of the conduit between the vessel and the chemical delivery system.

5. The substrate processing system of claim 4, wherein heat transfer fluid is selected from a fluorinated fluid, a hydrocarbon mineral oil and a silicone oil.

6. The substrate processing system of claim 5, wherein the heat transfer fluid has a boiling point in a range of from 55° C. to 270° C. and an operating temperature in a range of from −70° C. to 290° C.

7. The substrate processing system of claim 1, wherein the conduit further comprises an intermediate channel separating the outer channel and the inner channel.

8. The substrate processing system of claim 7, wherein the intermediate channel contains an inert material.

9. The substrate processing system of claim 8, wherein the inert material comprises a fluid.

10. The substrate processing system of claim 2, further comprising a layer of insulation surrounding the outer channel.

11. The substrate processing system of claim 7, further comprising a layer of insulation surrounding the outer channel.

12. The substrate processing system of claim 10, further comprising a heated enclosure containing a vapor receiving container between the vessel and the chemical delivery system.

13. The substrate processing system of claim 11, further comprising a heated enclosure containing a vapor receiving container between the vessel and chemical delivery system.

14. A method of delivering a chemical to a substrate processing chamber, the method comprising:
flowing from a vessel containing the chemical through an inner channel of a length of a conduit; and
maintaining the chemical flowing in the inner channel at a temperature variation of less than 10° C. along the length of the conduit between the vessel and a chemical delivery system which delivers the chemical as a vapor to the substrate processing chamber with a heat exchange fluid surrounding the inner channel.

15. The method of claim 14, wherein the heat exchange fluid is contained in an outer channel and flows from a heat exchanger to the chemical delivery system.

16. The method of claim 15, further comprising separating the outer channel and the inner channel with an intermediate channel containing an inert material.

17. The method of claim 15, further comprising regulating the temperature of the heat exchange fluid with a heat exchanger.

18. The method of claim 17, wherein the heat exchange fluid has a boiling point in a range of from 55° C. to 270° C. and an operating temperature in a range of from −70° C. to 290° C.

19. The method of claim 18, wherein the heat exchange fluid comprises a fluorocarbon, a hydrocarbon mineral oil and a silicone oil.

20. The method of claim 19, the length of the conduit between the vessel and the chemical delivery system is at least 20 feet (6.10 meters) and the temperature variation is less than 5° C. along the length of the conduit between the vessel and the chemical delivery system.
